(19) United States
(12) Patent Application Publication
(10) Pub. No.: US 2008/0023729 A1
(43) Pub. Date: Jan. 31, 2008

(54) Solid-state image sensor

(75) Inventor: Shinichiro Izawa, Atsugi-shi (JP)

Correspondence Address: OLIFF & BERRIDGE, PLC, P.O. BOX 320850, ALEXANDRIA, VA, 22320-4850, US

(73) Assignees: SANYO ELECTRIC CO., LTD., MORIGUCHI-SHI (JP); SANYO SEMICONDUCTOR CO., LTD., ORA-GUN (JP)

(21) Appl. No.: 11/878,725

(22) Filed: Jul. 26, 2007

(30) Foreign Application Priority Data
Jul. 27, 2006 (JP) 2006-204101

(51) Int. Cl. H01L 27/148

(52) U.S. Cl. 257/230; 257/E27.15

(57) ABSTRACT

In cases where AGP driving is applied to a CCD solid-state image sensor having a horizontal overflow drain structure, a problem arises in that the charges overflow into the second channel regions (8) from the overflow drain regions (14), and noise is superimposed on the information charges. The CCD solid-state image sensor has a plurality of first channel regions (4) that are disposed parallel to each other, overflow drain regions (14) that are disposed between neighboring first channel regions (4), a plurality of separation regions (12) that are disposed between the first channel regions (4) and overflow drain regions (14), and a plurality of first transfer electrodes (10) that are disposed parallel to each other over the plurality of first channel regions in the direction perpendicular to the first channel regions (4). In other to solve the problem described above, the CCD solid-state image sensor further comprises second channel regions (9) which are disposed in positions corresponding to the regions where the first channel regions (4) and specified first transfer electrodes (10) intersect, and which have a higher concentration than the first channel regions (4), and the overflow drain regions (14) adjacent to the second channel regions (8) have protruding parts (18) that protrude toward the second channel regions (8).

### CROSS-REFERENCE TO RELATED APPLICATION

The priority application number JP2006-204101 upon which this patent application is based is hereby incorporated by the reference.

### BACKGROUND OF THE INVENTION

1. Field of the Invention

The present invention relates to a CCD solid-state image sensor, and more specifically relates to an overflow drain structure.

2. Description of the Related Art

FIG. 1 is a schematic diagram showing the construction of a frame transfer CCD solid-state image sensor transfer. This frame transfer CCD solid-state image sensor transfer has an imaging section 50, a storage section 52, a horizontal transfer section 54, and an output section 56. The information charges generated in the imaging section 50 are transferred at high speed to the storage section 52. The storage section 52 can hold the information charges. The information charges held in the storage section 52 are transferred one line at a time to the horizontal transfer section 54, and are further transferred from the horizontal transfer section 54 to the output section 56 in single-pixel units. The output section 56 converts the amount of charge for each pixel into a voltage value, and the variation in the voltage value is output as a CCD output signal.

When an excessive information charge is generated in the imaging section 50, a phenomenon called “blooming” occurs, in which the information charges overflow into surrounding pixels. In order to suppress this blooming, an overflow drain structure is provided which discharges the unnecessary information charges. For example, the overflow drain structure may be a vertical overflow drain structure or a horizontal overflow drain structure, as described in Japanese Laid-Open Patent Application No. 2004-165479.

In the vertical overflow drain structure, an N well which is an N type diffusion layer, and underneath this, a P well which is a P type diffusion layer, are formed in the surface of an N type semiconductor substrate, and an NPN structure is formed in the direction of depth of the substrate. The excess charges of the front-surface photodiode cross the potential barrier formed by the P well, and is discharged into the substrate, as a result of the P well being depleted by the application of a positive voltage to the back surface of the substrate.

On the other hand, in the case of the horizontal overflow drain, a drain region comprising an N⁺ diffusion layer is disposed adjacent to a light-receiving pixel. As a result, there is no need for an NPN structure in the direction of depth of the substrate, and an N well used to construct a light-receiving pixel, CCD register, and the like, is formed in the front surface of a P type semiconductor substrate.

FIG. 2 is a plan view of essential parts in the vicinity of the boundary between the imaging section 50 and the storage section 52 of a solid-state image sensor having a horizontal overflow drain structure. FIG. 3 shows a cross section CS of the imaging section 50 and the potential distribution PD along line X-X′ shown in FIG. 2.

The plan structure of a solid-state image sensor having a horizontal overflow drain structure will be described with reference to FIG. 2. A plurality of channel regions 64 are disposed parallel to each other across the area extending from the imaging section 50 to the storage section 52. Separation regions 62 are disposed parallel to each other between the neighboring channel regions 64. An overflow drain region 66 is disposed in every other separation region 62. The width of the overflow drain regions 66 in the imaging section 50 is broader than the width of the overflow drain regions 66 in the storage section 52. Transfer electrodes 60-1 through 60-3 that are used to transfer the information charges along the channel regions 64 are arranged periodically in the channel direction in the imaging section 50 and storage section 52. One set of transfer electrodes 60-1 through 60-3 is provided for each pixel.

The stacked structure of the solid-state image sensor having a horizontal overflow drain structure will be described with reference to cutaway view shown in FIG. 3. The channel regions 64 are formed by the ion implantation of an N type impurity, and the diffusion process of this N type impurity, in the principal surface of a P type semiconductor substrate (P-sub) 68. Together with the P-sub 68, the channel regions 64 form photodiodes. The separation regions 62 are formed by the ion implantation of a P type impurity, and the diffusion process of this P type impurity. The separation regions 62 are disposed in the gaps between the channel regions 64, and electrically separate the channel regions 64. The overflow drain regions 66 are formed inside the separation regions 62 by the ion implantation and diffusion treatment of an N type impurity. An insulating oxide film 70 and transfer electrodes 60 are successively formed on the P-sub 68 in which the overflow drain regions 66 and the like are formed.

The potential distribution during image capture will be described with reference to FIG. 3. The horizontal axis of the potential diagram PD indicates the potential along the line X-X′, and the vertical axis indicates potential at various positions. The positive potential increases in the downward direction. The potential distribution shown in FIG. 3 indicates a case in which a positive potential is applied to the transfer electrodes 60-1 and 60-2, and a negative potential is applied to the transfer electrodes 60-3. The channel regions 64 form potential wells 76 that are depleted by the voltage that is applied to the transfer electrodes 60. During image capture, information charges can be accumulated in these potential wells 76. A predefined potential is applied to the overflow drain regions 66, and potential wells 74 (drain regions) that are deeper than the potential wells 76 are formed. The separation regions 62 form potential barriers 72 and 78 between neighboring channel regions 64, or between channel regions 64 and overflow drain regions 66. In the horizontal overflow drain structure, in cases where an excess information charges are generated in or caused to flow into the potential wells 76, the excess information charges can be caused to cross the potential barriers 78, and can be discharged into the overflow drain regions 74. As a result, blooming, in which the excess charges overflow into surrounding pixels, can be suppressed.

In the construction shown in FIGS. 2 and 3, overflow drain regions 66 are formed in the separation regions 62 of every other column, and there are separation regions 62 in which overflow drain regions 66 are formed, and separation regions 62 in which overflow drain regions 66 are not formed. As a result of the effect of the overflow drain regions 66, the height of the potential barriers 78 formed by the separation regions 62 in which overflow drain regions 66 are formed is lower than the height of the potential barriers 72 formed by separation regions 62 in which overflow drain regions 66 are not formed. A potential barrier 72 and potential barrier 78 having different heights are formed on either side of each channel region 64. The excess information charges generated in the potential wells 76 cross the potential barriers 78, and are discharged into the overflow drain regions 66.

FIG. 4 shows the potentials applied to the transfer electrodes and overflow drains in the respective operations of accumulation (image capture), transfer and discharge of the information charges in the CCD solid-state image sensor having a conventional overflow drain structure.

First, discharge driving called an electronic shutter is performed immediately prior to image capture (t<t0). This electronic shutter operation causes the potential (OFD) applied to the overflow drain regions 66 to vary from a predetermined low potential (L) to a predetermined high potential (H), so that the information charges generated in the potential wells 76 are discharged into the overflow drain regions 66. In this case, a low potential is applied to the transfer electrodes 60-1, 60-2 and 60-3 (i.e., φ1, φ2, φ3=L), and the information charges accumulated in the channel regions 64 are discharged into the neighboring overflow drain regions 66 from the entire barrier on the side of the potential wells 76.

Subsequently, the OFD falls from H to L, and φ1 and φ2 rise from L to H, so that image capture is initiated (t=t0). During image capture, potential wells 76 are formed in the channel regions 64 beneath the transfer electrodes 60-1 and 60-2 to which φ1 and φ2 are applied, and information charges are accumulated in these potential wells 76. After the end of the image capture period, information charges are transferred in accordance with the transfer clock φ1 through φ3 applied to the transfer electrodes 60-1 through 60-3 (t≧t1). Here, the OFD during transfer driving maintains an L level.

At time t=t1, φ1 falls from H to L. As a result, the information charges accumulated in the regions beneath the transfer electrodes 60-1 and 60-2 are concentrated beneath the transfer electrode 60-2. At time t=t2, φ3 rises from L to H. As a result, the information charges stored beneath the transfer electrode 60-2 spread to the region beneath the transfer electrode 60-3. When φ2 falls from H to L at time t=t3, the information charges stored beneath the transfer electrodes 60-2 and 60-3 are concentrated beneath the transfer electrode 60-3. When φ1 rises from L to H at time t=t4, the information charges stored beneath the transfer electrode 60-3 spread downward from the transfer electrode 60-3. When φ3 falls from H to L at time t=t5, the information charges stored beneath the transfer electrodes 60-3 and 60-1 are concentrated beneath the transfer electrode 60-1. When φ2 rises from L to H at time t=t6, the information charges stored beneath the transfer electrode 60-1 spread to the region beneath the transfer electrode 60-2, and the information charges are stored in the regions beneath the transfer electrodes 60-1 and 60-2. As a result of this operation being repeated, the information charges are successively transferred along the channel regions 64.

In the CCD solid-state image sensor having the horizontal overflow drain structure described above, it is necessary to apply different positive and negative potentials to the transfer electrodes 60-1 through 60-3, and to form a potential well demarcated by potential barriers in the channel direction for each pixel, in order to accumulate information charges for each pixel during image capture driving.

In the case of the CCD solid-state image sensor having a vertical overflow drain structure, a technique called AGP (all gates pinning) is known in which a negative potential is applied to all of the transfer electrodes 60-1 through 60-3, and the gates are placed in an “off” state (for example, see Japanese Laid-Open Patent Application No. 2006-135).

FIG. 5 is a schematic plan view of a CCD solid-state image sensor having a vertical overflow drain structure. FIG. 6 is a cross section along line X-X′ in FIG. 5. FIG. 7 shows the potential distribution along line A-A′ in FIG. 6.

The plan structure of a vertical overflow drain will be described in concrete terms with reference to FIG. 5. First channel regions 94 are formed parallel to each other across the imaging section 50 and storage section 52 (not shown in FIG. 5). Separation regions 98 are formed parallel to each other between neighboring first channel regions 94. Transfer electrodes 100-1 through 100-3 are caused to extend parallel to each other in the direction perpendicular to the direction of extension of the first channel regions 94. Second channel regions 96 are formed in the regions where the first channel regions 94 and transfer electrodes 100-1 intersect.

The stacked structure of the vertical overflow drain will be described in concrete terms with reference to FIG. 6. A P well 92 in which a P type impurity is diffused is disposed in the front surface region of an N type semiconductor substrate (N-sub) 90. Furthermore, first channel regions 94 in which an N type impurity is diffused are disposed in the front surface of the P well 92. During transfer driving, these first channel regions 94 constitute transfer channels for the information charges. Furthermore, separation regions 98 in which a high concentration of a P type impurity is diffused are formed in the gaps between the first channel regions 94, and electrically separate neighboring first channel regions 94. An insulating film 102 is formed on top of the semiconductor substrate 90 in which impurities are diffused, and transfer electrodes 100-1 through 100-3 are formed on top of the insulating film 102.

In AGP driving, for example, one transfer electrode (the transfer electrode 100-1) is selected from the transfer electrodes 100-1 through 100-3 disposed on one pixel, and a second channel region 96 to which a high concentration of an N type impurity is added is selectively formed in the first channel region 94 beneath this transfer electrode. Because of the difference in the impurity concentration between the first channel regions 94 and second channel regions 96, the potential beneath the transfer electrodes 100-1 where the second channel regions 96 are formed are deeper than the potential beneath the other transfer electrodes 100-2 and 100-3, and potential wells are formed beneath the transfer electrodes 100-1, even in cases where a negative potential is applied to all of the transfer electrodes, and the gates are placed in an “off” state. In this structure, image capture can be performed by applying a negative potential to all of the transfer electrodes, and the information charges that are generated during the exposure period are accumulated in the second channel regions 96 beneath the transfer electrodes 100-1. In this case, holes are concentrated in the vicinity of the front surfaces of the first channel regions 94, and these holes are pinned to the interface states that are present at the interface between the semiconductor substrate 90 and the insulating film 102. As a result of the interface states being filled by these pinned holes, the dark current that is generated during the exposure period is reduced, and noise can be prevented from mixing with the information charges, which is generated along with the dark current.

FIG. 7 shows the potential distribution along line A-A′ (direction of depth of the semiconductor) in FIG. 6. In the case of a vertical overflow drain structure, a potential distribution such as that indicated by the solid line 110 is formed during image capture, and the information charges accumulated in the second channel regions 96 are prevented from leakage to the back surface side of the semiconductor substrate 90. During electronic shuttering, a high potential is applied to the back surface side of the semiconductor substrate 90, so that the potential distribution varies from that indicated by the solid line 110 to that indicated by the broken line 112, and the information charges can be discharged to the back surface side of the semiconductor substrate 90.

FIG. 8 is a driving timing chart for a case in which AGP driving is performed. First, immediately prior to the accumulation of the information charges (t<t0), the voltage level Vsub that is applied to the back surface side of the semiconductor substrate 90 is raised from a low potential (L) to a high potential (H). As a result, the information charges accumulated in the regions beneath the transfer electrodes 100-1 are discharged to the back surface side of the semiconductor substrate 90. Subsequently, Vsub falls from H to L, so that image capture is initiated (t=t0). After the information charges are accumulated for a specified time in the regions beneath the transfer electrodes 100-1, the information charges are transferred by frame transfer.

When φ2 rises from an L level to an H level at time t=t1, the information charges are transferred from the regions beneath the transfer electrodes 100-1 to the regions beneath 100-2. When φ3 rises from an L level to an H level at time t=t2, the information charges stored in the regions beneath the transfer electrodes 100-2 spread to the regions beneath the transfer electrodes 100-3. When φ2 falls from an H level to an L level at time t=t3, the information charges stored in the regions beneath the transfer electrodes 100-2 and 100-3 are concentrated in the regions beneath the transfer electrodes 100-3. When φ1 rises from an L level to an H level at time t=t4, the information charges stored in the regions beneath the transfer electrodes 100-3 spread to the regions beneath the transfer electrodes 100-1. When φ3 falls from H to L at time t=t5, the information charges stored in the regions beneath the transfer electrodes 100-3 and 100-1 are concentrated in the regions beneath the transfer electrodes 100-1. When φ2 rises from L to H at time t=t6, the information charges stored in the regions beneath the transfer electrodes 100-1 spread to the regions beneath the transfer electrodes 100-2. When φ1 falls from H to L at time t=t7, the information charges stored in the regions beneath the transfer electrodes 100-1 and 100-2 are concentrated, and are stored only in the regions beneath the transfer electrodes 100-2. As a result of the repetition of such an operation, the information charges are successively transferred along the first channel regions 94.

The vertical overflow drain driving method using this AGP driving differs greatly from the driving method of the horizontal overflow drain structure shown in FIG. 4, in that a negative potential (L) is applied to all of the transfer electrodes 100 during the image capture period, and in that specified transfer electrodes are placed at a high potential (H), i.e., at an ON voltage, when the period shifts from the image capture period to the transfer period.

From the standpoint of suppressing the superimposition of noise on the information charges due to dark current, it is conceivable that AGP driving might be applied to a CCD solid-state image sensor having a horizontal overflow drain structure. However, when AGP driving is applied to a conventional horizontal overflow drain structure, the information charges cannot be transferred in a normal manner. Specifically, in the case of a transfer operation in which the information charges stored in the second channel regions beneath two transfer electrodes are concentrated in the second channel region beneath a single transfer electrode, there may be instances in which the potential barrier between the overflow drain region and the second channel region is eliminated by the high voltage (H) that is applied to the single transfer electrode, and the charges overflow into the second channel region from the overflow drain region. As a result, the problem of the superimposition of noise on the information charges arises.

### SUMMARY OF THE INVENTION

The present invention was devised in order to solve the problems described above. The present invention provides a CCD solid-state image sensor having a horizontal overflow drain structure that prevents the superimposition of noise on the information charges during transfer driving by AGP driving.

The solid-state image sensor of the present invention has a plurality of first channel regions of a second conduction type which are disposed parallel to each other on a principal surface of a semiconductor substrate of a first conduction type, overflow drain regions of the second conduction type which are disposed between neighboring first channel regions, a plurality of separation regions of the first conduction type which are disposed between the first channel regions and the overflow drain regions, and a plurality of first transfer electrodes which are formed over the plurality of first channel regions and which are disposed parallel to each other in a direction perpendicular to the plurality of first channel regions. The solid-state image sensor of the present invention further has second channel regions of the second conduction type which are disposed on the principal surface of the semiconductor substrate in positions corresponding to the regions where the first channel regions and specified first transfer electrodes intersect, and which have a higher concentration than the first channel regions, and the overflow drain regions adjacent to the second channel regions have protruding parts that protrude toward the second channel regions.

### BRIEF DESCRIPTION OF THE DRAWINGS

FIG. 1 is a schematic diagram of a frame transfer CCD solid-state image sensor of the present embodiment and the prior art;

FIG. 2 is a schematic plan view of a CCD solid-state image sensor having a conventional horizontal overflow drain structure;

FIG. 3 is a schematic diagram showing a cross section and potential distribution of a CCD solid-state image sensor having a conventional horizontal overflow drain structure;

FIG. 4 is a timing chart for a CCD solid-state image sensor having a conventional horizontal overflow drain structure;

FIG. 5 is a plan view of a CCD solid-state image sensor having a conventional vertical overflow drain structure;

FIG. 6 is a cross section of a CCD solid-state image sensor having a conventional vertical overflow drain structure;

FIG. 7 is a schematic diagram showing the potential distribution of a CCD solid-state image sensor having a conventional vertical overflow drain structure;

FIG. 8 is a timing chart for a CCD solid-state image sensor having a conventional vertical overflow drain structure;

FIG. 9 is a schematic plan view of a CCD solid-state image sensor constituting an embodiment of the present invention;

FIG. 10 is a schematic diagram showing a cross section and potential distribution along line X-X′ in the CCD solid-state image sensor shown in FIG. 9;

FIG. 11 is a schematic diagram showing a cross section and potential distribution along line Y-Y′ in the CCD solid-state image sensor shown in FIG. 9;

FIG. 12 is a schematic diagram showing a cross section and potential distribution along line Z-Z′ in the CCD solid-state image sensor shown in FIG. 9;

FIG. 13 is a schematic diagram illustrating the potential distribution in the electronic shutter operation of a CCD solid-state image sensor constituting an embodiment of the present invention;

FIG. 14 is a timing chart of AGP driving;

FIG. 15 is a diagram showing the transfer of the charges by AGP driving in schematic terms;

FIG. 16 is a diagram showing the transfer of the charges by AGP driving in schematic terms;

FIG. 17 is a diagram showing the transfer of the charges by AGP driving in schematic terms;

FIG. 18 is a schematic diagram of the potential distribution illustrating AGP driving in an embodiment of the present invention;

FIG. 19 is a schematic plan view of a CCD solid-state image sensor constituting a second embodiment of the present invention; and

FIG. 20 is a schematic plan view of a CCD solid-state image sensor constituting a third embodiment of the present invention.

### DESCRIPTION OF THE PREFERRED EMBODIMENTS

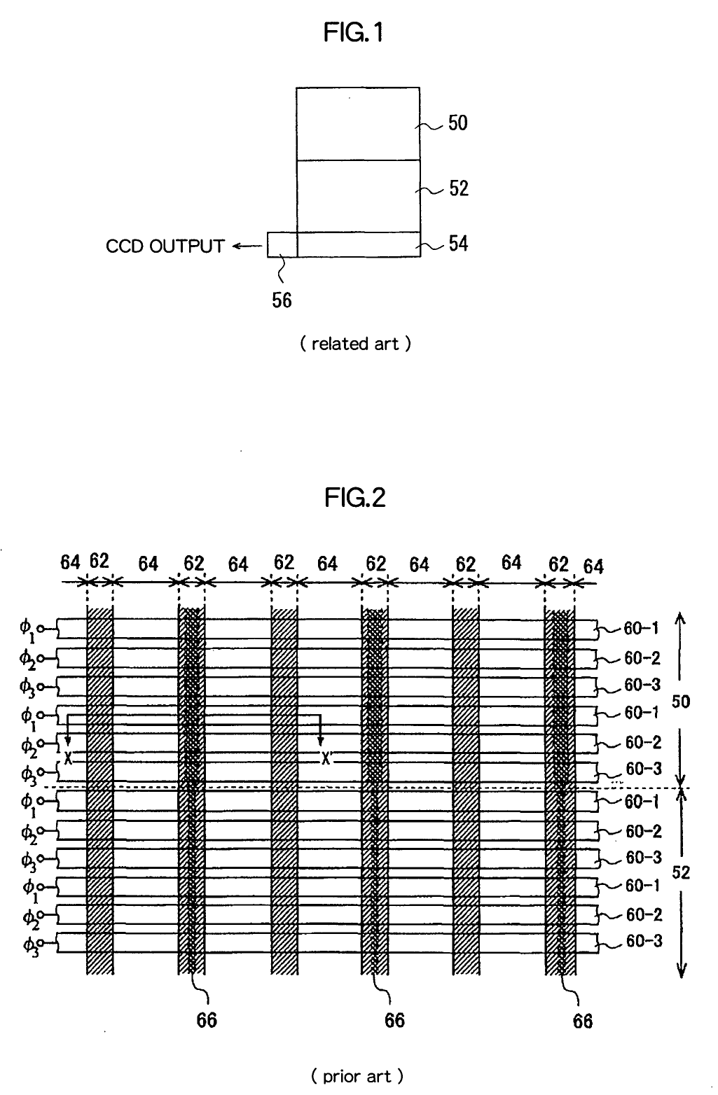

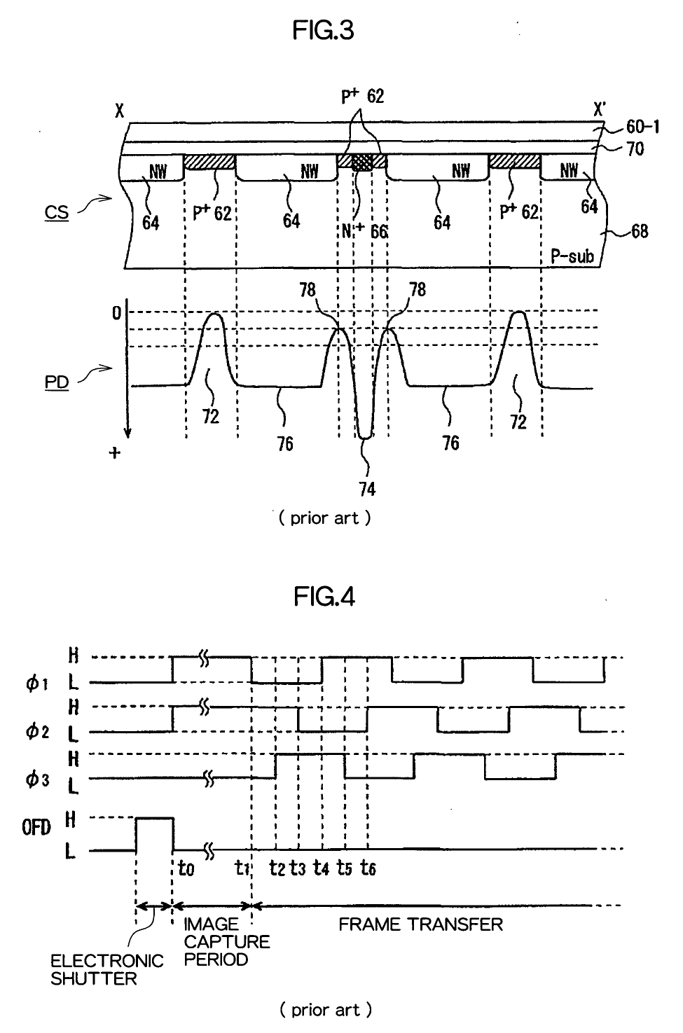

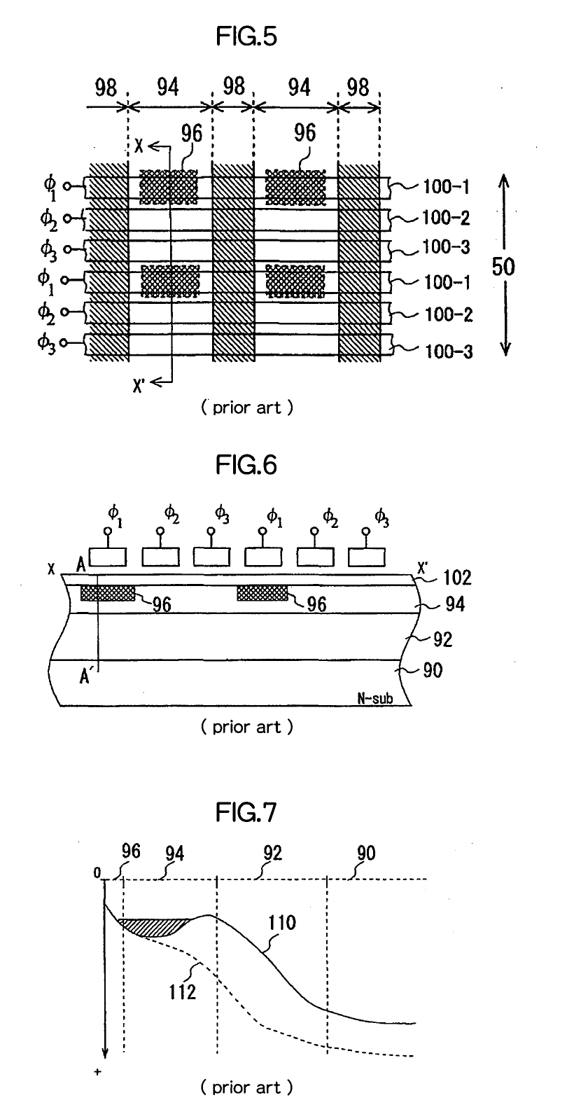

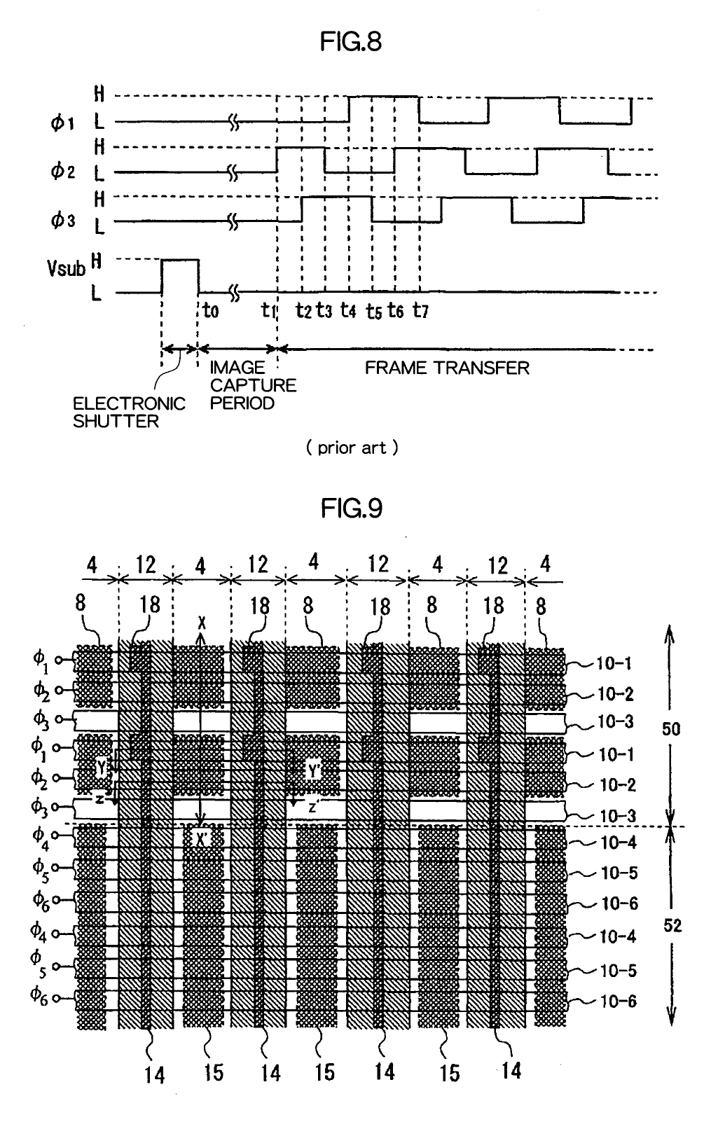

CCD solid-state image sensors constituting embodiments of the present invention will be described in detail with reference to the attached drawings. As in FIG. 1, the overall structures of the CCD solid-state image sensors of these embodiments are basically constructed from an imaging section 50, a storage section 52, a horizontal transfer section 54 and an output section 56.

### Embodiment 1

### Structure of CCD Solid-State Image Sensor

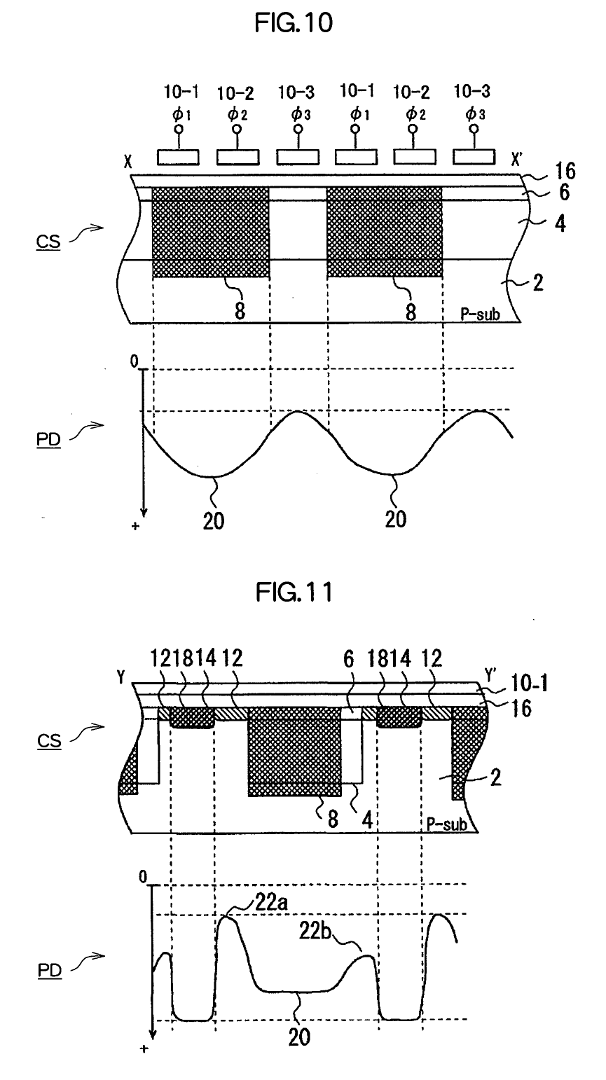

FIG. 9 shows a plan view of the area in the vicinity of the boundary between the imaging section 50 and storage section 52 in a CCD solid-state image sensor constituting Embodiment 1 of the present invention. Furthermore, FIG. 10 shows a cross section CS and potential distribution PD along line X-X′ of the imaging section 50 in FIG. 9. FIG. 11 shows a cross section and potential distribution along line Y-Y′ of the imaging section 50 in FIG. 9.

First, the plan structure of the imaging section 50 of the CCD solid-state image sensor in the present embodiment will be described with reference to FIG. 9. A plurality of first channel regions 4 are disposed parallel to each other in the imaging section 50. The plurality of first channel regions 4 are formed with predefined gaps left between these regions, and a plurality of separation regions 12 are disposed parallel to each other in these gaps. The first channel regions 4 are electrically demarcated by the two neighboring separation regions 12. The first channel regions 4 demarcated by these separation regions 12 constitute transfer paths for information charges. Here, it is desirable that the first channel regions 4 and separation regions 12 are disposed without any gaps left in between.

A plurality of first transfer electrodes 10-1 through 10-3 are formed parallel to each other in the direction perpendicular to the direction of extension of the first channel regions 4. Here, a set of three transfer electrodes 10 (transfer electrodes 10-1 through 10-3) is caused to correspond to each pixel.

Second channel regions 8 are disposed inside the first channel regions 4 in the vicinity of the regions where the first channel regions 4 and the two transfer electrodes 10-1 and 10-2 intersect. Here, the second channel regions 8 are formed in positions in which the transfer electrodes 10-1 and 10-2 are superimposed, and are not formed in positions in which the transfer electrodes 10-3 are superimposed. Furthermore, it is desirable that one side of each second channel region 8 is formed with a gap left between this side and the separation region 12, and that the other side be formed with no gap left between this other side and the separation region 12. As a result of the first channel regions being disposed between the second channel regions and the separation regions, higher potential barriers are formed between the second channel regions and the drain regions, and the superimposition of noise on the information charges can be reliably prevented.

Overflow drain regions 14 are disposed in the separation regions 12. The overflow drain regions 14 are formed extending parallel to the first channel regions 4 in the vicinity of center of each separation region 12, and have protruding parts 18 that protrude toward the second channel regions 8 in the vicinity of the regions where the second channel regions 8 are disposed. The protruding parts 18 are formed corresponding to the respective second channel regions 8, and protrude toward one of the neighboring second channel regions 8 in the row direction (i.e. the horizontal direction in the figure). As a result of the protruding parts protruding toward one of the neighboring second channel regions, the overflow of the charges into the second channel region from the side of the drain region that has no protruding part can be prevented.

The protruding parts 18 in Embodiment 1 are disposed beneath the transfer electrodes 10-1 among the transfer electrodes 10-1 and 10-2 disposed in the regions where the second channel regions 8 are formed. However, it would also be possible to dispose these protruding parts 18 beneath the transfer electrodes 10-2. Furthermore, the protruding parts 18 are shown as having a rectangular shape, but the present invention is not limited to this configuration. Moreover, drain electrodes not shown in the figures are connected to the overflow drain regions 14, and a voltage is applied to the overflow drain regions 14 via the drain electrodes.

In the present embodiment, three first transfer electrodes 10-1, 10-2, and 10-3 that are adjacent to each other are disposed in the direction of extension of the first channel regions 4 for each pixel. However, the present invention is not limited to this. For example, if the set of transfer electrodes 10 corresponding to one pixel is N electrodes, then second channel regions 8 may be disposed beneath 2 to (N−1) first transfer electrodes 10. In this case, it is desirable that the protruding parts 18 be disposed in regions beneath 1 to (N−2) transfer electrodes 10.

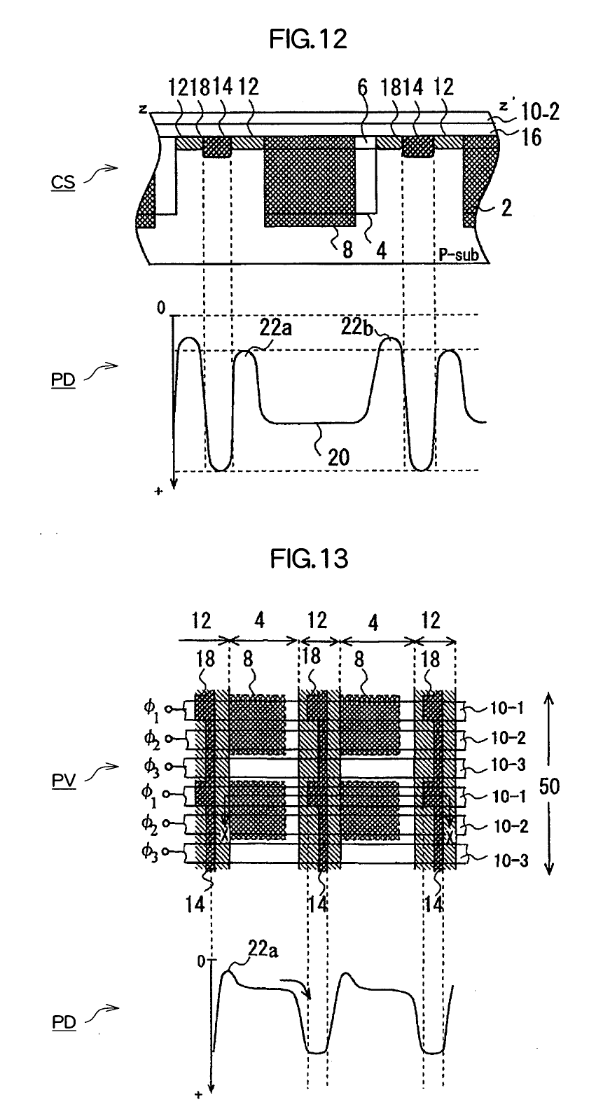

Next, the stacked structure of the solid-state image sensor in Embodiment 1 will be described with reference to the cross sections CS shown respectively in FIG. 10, FIG. 11, and FIG. 12. First channel regions 4 doped with an N type impurity are formed in the front surface region of a P type substrate (P-sub) 2. For example, a general semiconductor material such as a silicon substrate or the like can be used as the semiconductor substrate 2, and phosphorus (P), arsenic (As), or the like can be used as an N type impurity.

Furthermore, regions 6 in which an N type impurity is ion-implanted and subjected to a diffusion process are formed so that these regions are superimposed on the first channel regions 4 in the front surface region of the semiconductor substrate 2. As a result of the formation of these regions, the information charges that are stored in the potential wells described later can be increased.

Furthermore, in the front surface region of the semiconductor substrate 2, a plurality of second channel regions 8 which are set more deeply into the semiconductor substrate 2 than the first channel regions 4 are formed in the regions beneath at least two of the set of transfer electrodes 10-1 through 10-3 corresponding to one pixel (in the present embodiment, the first transfer electrodes 10-1 and 10-2). Here, it is desirable that the second channel regions 8 be formed using the same type of impurity as that used in the first channel regions 4. Since the second channel regions 8 are formed by the further ion implantation of an N type impurity into the regions where the first channel regions 4 are disposed, these second channel regions 8 constitute N type semiconductor regions that have a higher concentration than the first channel regions 4.

Separation regions 12 in which a P type impurity is ion-implanted and subjected to a diffusion process are disposed in the gaps between the first channel regions 4. Boron (B), boron fluoride (BF2), or the like can be used as the P type impurity with which the separation regions 12 are doped.

Overflow drain regions 14 in which an N type impurity is ion-implanted at a high concentration are formed in the separation regions 12 to a greater depth than the separation regions 12.

An insulating film 16 is formed on the front surface of the semiconductor substrate 2 in which the first channel regions 4 and the like are disposed. A silicon material such as a silicon oxide film, silicon nitride film, or the like, a titanium dioxide material, or the like, can be used as the insulating film 16.

A plurality of first transfer electrodes 10 are formed parallel to each other on the insulating film 16, so that these electrodes are perpendicular to the direction of extension of the first channel regions 4. A conductive material such as a metal, polysilicon, or the like, can be used as the first transfer electrodes 10; furthermore, multi-layer structures comprising a silicon nitride (SiN) layer and a polysilicon (polysi) layer can also be used. The anti-reflection function is improved by forming polysi with SiN interposed on the insulating film 16. Furthermore, in the imaging section 50, since light is received by the PN junction type photodiodes located beneath the first transfer electrodes 10, and a photoelectric conversion is performed, it is necessary to form the first transfer electrodes 10 with a thickness that is small enough to allow the transmission of light in cases where these electrodes are formed from a metal.

Next, the structure of the present embodiment in the storage section 52 will be described with reference to FIG. 9. In the storage section 52, first channel regions 4, separation regions 12, and overflow drain regions 14 are formed extending from the imaging section 50. Unlike the case of the imaging section 50, the overflow drain regions 14 disposed in the storage section 52 do not have protruding parts 18. Furthermore, third channel regions 15 that are doped with an N type impurity are formed in the first channel regions 4 of the storage section 52. The third channel regions 15 are formed inside the first channel regions 4, with gaps left between these regions 15 and the neighboring separation regions 12. Accordingly, the overflow of charges that cause noise into the third channel regions 15 from the overflow drain regions 14 can be more reliably prevented.

Moreover, an insulating film 16 is formed on the semiconductor substrate 2, and second transfer electrodes 10-4 through 10-6 that are used in order to successively transfer the information charges to the horizontal transfer section 54 are formed on this insulating film 16 in the same manner as in the case of the imaging section 50. The information charges can be successively transferred by applying three-phase transfer clocks φ4 through φ6 having three different phases to these second transfer electrodes 10-4 through 10-6.

Furthermore, since there is no need to discharge the information charges into the drain regions 14 in the storage section 52, drain regions need not be installed. In this case, it is desirable that the third channel regions 15 be disposed without any gaps being left between these regions 15 and the separation regions 12.

### <Potential Distribution>

Next, the potential distribution during image capture by AGP driving in the CCD solid-state image sensor of the present embodiment will be described. The potential distribution PD shown in FIG. 10 indicates the variation in the potential along line X-X′ in FIG. 9. The horizontal axis of this potential distribution indicates the distance in the direction of extension of first channel regions 4, and the cross section CS shown above is shown in correspondence with the positions in this direction. The vertical axis shows the potential at the depth corresponding to the transfer channels of the information charges; down is the positive potential side, and up is the negative potential side. The potential distribution PD shown in FIG. 11 shows the variation in the potential along line Y-Y′, and the potential distribution PD shown in FIG. 13 shows the variation in the potential along line Z-Z′. The horizontal axes of these potential distributions PD indicate the distance in the direction of extension of the first transfer electrodes 10, and the cross sections CS shown above are shown in correspondence with the positions in this direction. As in the potential distribution PD shown in FIG. 10, the vertical axes indicate the potential at respective positions. Furthermore, during image capture, a common negative potential (e.g., −5.7 V) is applied to the respective first transfer electrodes 10, and a low potential (e.g., 3.5 V) is applied to the overflow drain regions 14.

In the direction of extension of the first channel regions 4, as is shown by the cross section CS in FIG. 10, second channel regions 8 are formed in which a higher concentration of the impurity is doped than in the first channel regions 4. Accordingly, as is shown by the potential distribution PD in FIG. 10, potential wells 20 caused by the difference in the impurity concentration are formed even in cases where the same negative potential is applied to all of the first transfer electrodes 10.

In the direction of extension of the first transfer electrodes 10-1, as is shown in FIG. 11, potential barriers 22a and 22b caused by the separation regions 12 are formed between the first and second channel regions 4 and 8 and the overflow drain regions 14; furthermore, potential wells 20 are formed in the second channel regions 8. In the present embodiment, the protruding parts 18 of the overflow drain regions 14 extend toward only one of the neighboring first channel regions 4 on both sides; accordingly, in the cross section along line Y-Y′, the overflow drain regions 14 are positioned asymmetrically with respect to the first channel regions 4. As a result of this asymmetry, the heights of the potential barriers 22a and 22b differ from each other, and the potential distribution also has an asymmetrical shape.

In FIG. 12 as well, potential barriers 22a and 22b and potential wells 20 similar to those shown in FIG. 11 are formed. Here, since the second channel regions 8 are formed toward only one of the neighboring separation regions 12 on both sides, the distances from the second channel regions 8 of the two overflow drain regions 14 formed on both sides of the second channel regions 8 differ from each other. As a result, the heights of the potential barriers 22a and 22b generated between the second channel regions 8 and the overflow drain regions 14 are different.

During image capture in which a common negative potential is applied to the respective first transfer electrodes 10, the information charges are accumulated in the potential wells 20 shown in FIGS. 10, 11, and 12. The potential barriers 22a and 22b can prevent the information charges accumulated in the potential wells 20 from overflowing into the overflow drain regions 14.

FIG. 13 shows a plan view PV of the imaging section 50 during discharge driving (electronic shuttering), and the potential distribution PD in the cross section along line X-X′ shown in this plan view. During discharge driving, a negative potential is applied to all of the first transfer electrodes 10 in the same manner as in the case of image capture driving, and a potential that is higher than that applied during image capture driving is applied to the overflow drain regions 14. Since the potential barriers 22b on the side of the protruding parts 18 are eliminated by the high potential that is applied to the overflow drain regions 14, the information charges accumulated in the potential wells 20 is discharged into the overflow drain regions 14 via the protruding parts 18.

Since the protruding parts 18 in Embodiment 1 are disposed on only one side of each overflow drain region 14, it is possible to prevent the discharge of the information charges into the overflow drain regions 14 from the second channel region 8 that is adjacent to the other side on which no protruding part 8 is disposed. Furthermore, although this is not shown in the drawings, protruding parts 18 are not disposed in the regions beneath the first transfer electrodes 10-2; accordingly, there is almost no discharge of the information charges from these regions.

### <AGP Driving Method>

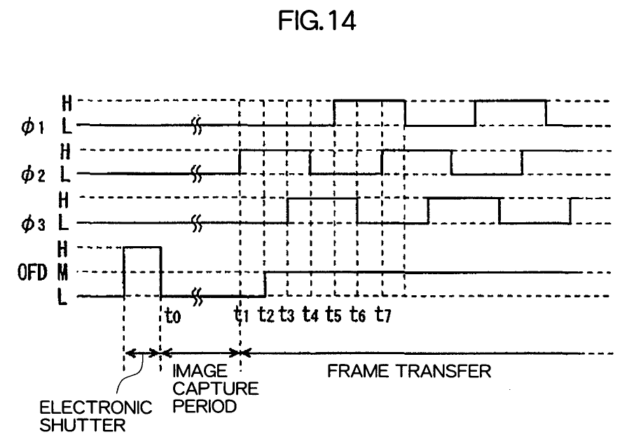

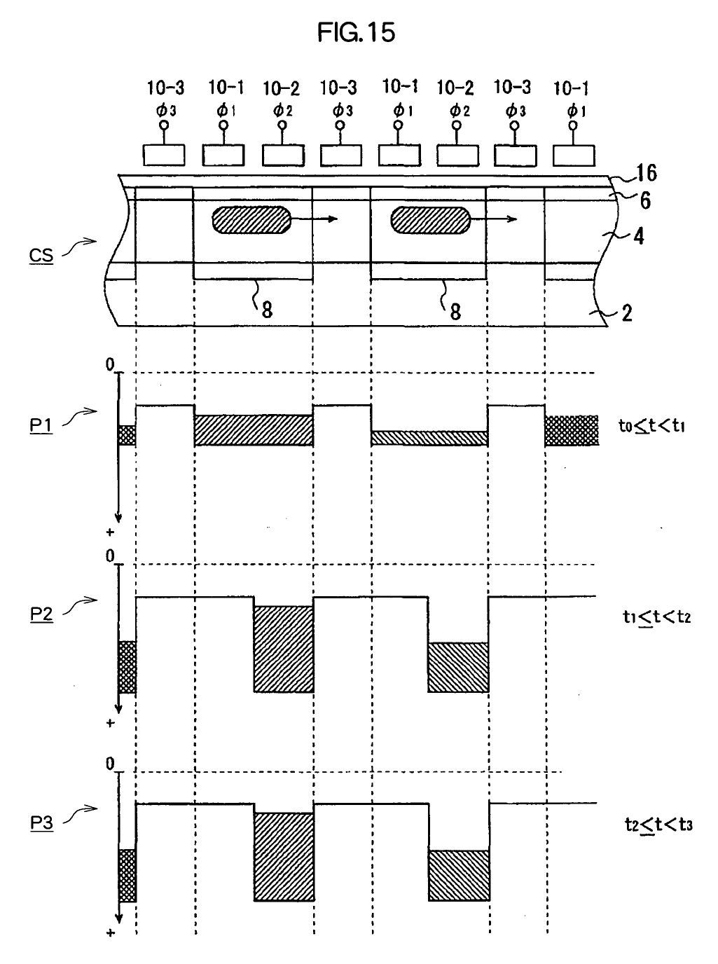

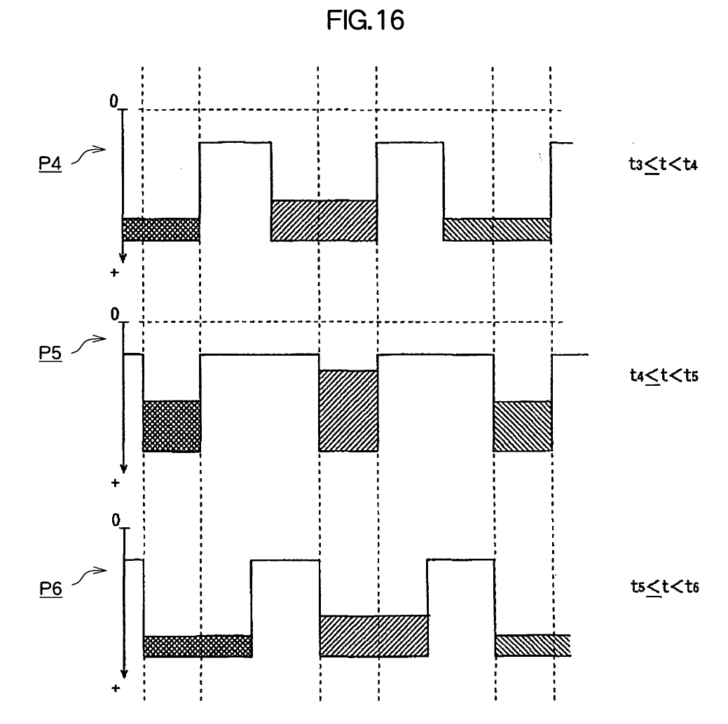

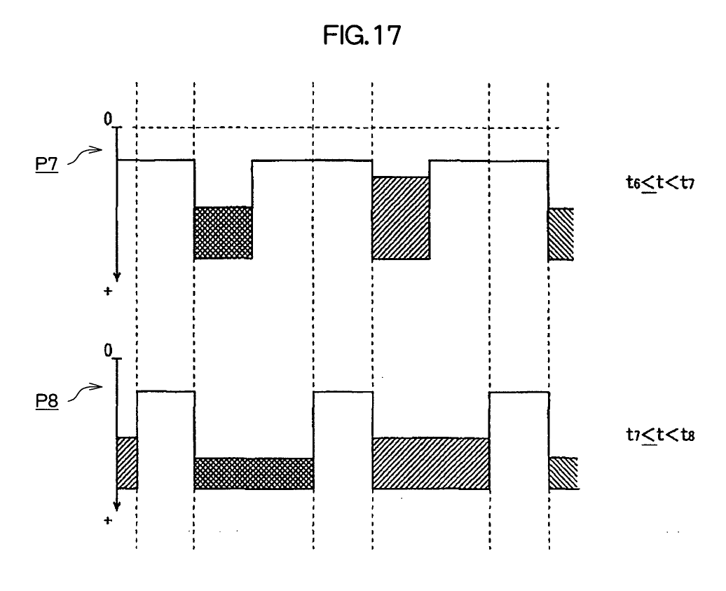

The information charge accumulation, discharge, and transfer methods using AGP driving in the present embodiment will be described. FIG. 14 is a timing chart of AGP driving in the present embodiment. FIGS. 15 through 17 are schematic diagrams showing the conditions of the variation in the potential distribution during accumulation driving and transfer driving. The potential distributions P1 through P8 shown in FIGS. 15 through 17 have horizontal axes that indicate the position along the charge transfer direction; all of these indicate the variation in potential in the charge transfer channels indicated by the cross section CS in FIG. 15. For purposes of simplification, the potential distributions P1 through P8 show the variation in potential at right angles. The respective potential distributions P1 through P8 show the information charges stored in the potential wells schematically by means of hatching.

First, the potential (OFD) that is applied to the overflow drain regions 14 immediately prior to image capture rises from a low potential (L) to a high potential (H), so that the information charges are discharged into the overflow drain regions 14 (t<t0). In this case, a negative potential (L) is applied to all of the transfer electrodes 10, and the information charges accumulated in the potential wells formed in the regions beneath the transfer electrodes 10-1 and 10-2 are discharged into the neighboring overflow drain regions 14 via the protruding parts 18 disposed in these overflow drain regions 14. Here, for example, the low potential that is applied to the OFD is 4 V, and the high potential is 14 V.

At time t=t0, the OFD falls from an H level to an L level, so that image capture is initiated. During image capture, an L level is applied to all of the transfer electrodes 10. In this case, an information charges are accumulated in the second channel regions 8 (state of potential distribution P1).

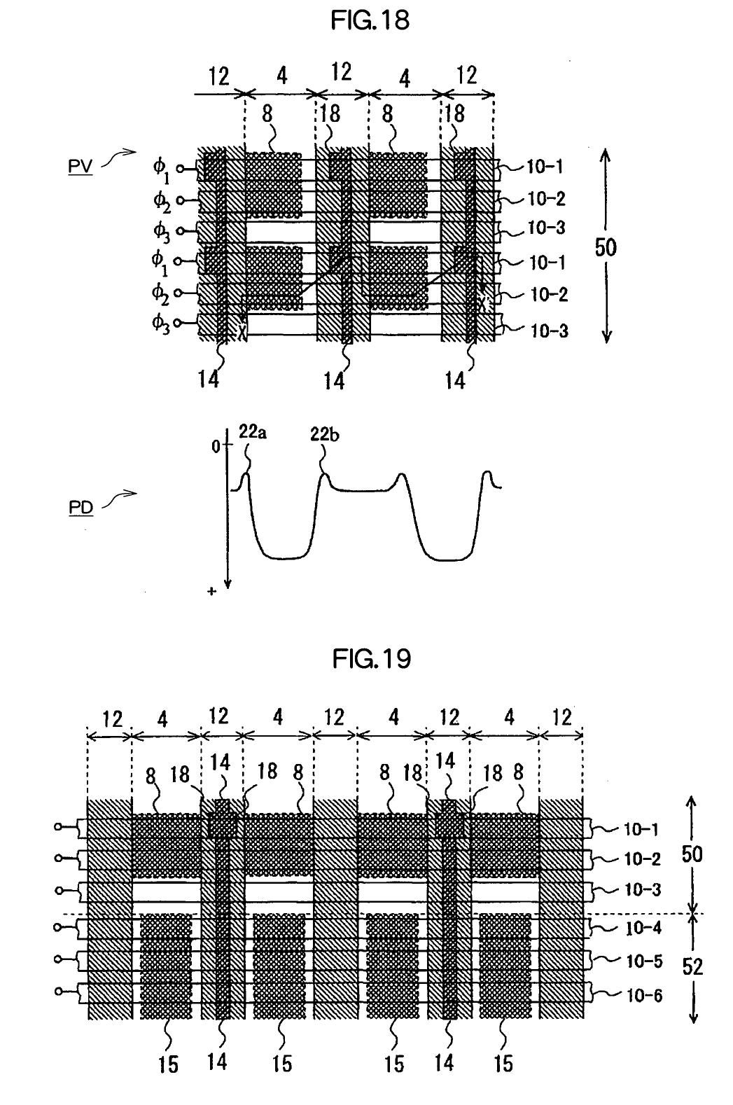

The image capture period ends at time t=t1, and the accumulated information charges are transferred by frame transfer. At time t=t1, the potential φ2 that is applied to the transfer electrodes 10-2 rises from an L level to an H level. As a result, the potential beneath the transfer electrodes 10-2 increases in the positive direction, i.e., the potential wells becomes deeper, and the information charges accumulated in the regions beneath the transfer electrodes 10-1 and 10-2 are transferred to the regions beneath the transfer electrodes 10-2 (state of potential distribution P2). In other words, the information charges accumulated in the regions beneath the transfer electrodes 10-1 and 10-2 are transferred to the regions beneath the transfer electrodes 10-2 corresponding to the positions where no protruding parts 18 are formed among the two transfer electrodes 10-1 and 10-2. Here, the OFD maintains an L level. The potential distribution in this case is shown in FIG. 18. FIG. 18 shows a plan view PV in the imaging section 50, and the potential distribution PD along the bent line X-X′ shown above this plan view PV. With the OFD maintained at an L level, the potential barrier 22b is maintained even if the information charges are transferred, since no protruding parts 18 are disposed in the regions beneath the transfer electrodes 10-2, which constitute the transfer destination. As a result, movement of the charges between the overflow drain regions 14 and second channel regions 8 via the protruding parts 18 does not occur, and the superimposition of noise on the information charges can be prevented.

After the information charges are transferred to the regions beneath the transfer electrodes 10-2 where no protruding parts 18 are disposed, the OFD rises from the low potential (L) to an intermediate potential (M) at t=t2 (state of potential distribution P3). During the subsequent frame transfer period, the OFD is held at the intermediate potential. For example, the intermediate potential is 8 V. As a result of transfer driving being performed at an intermediate potential, the overflow of the information charges into the overflow drain regions 14 from the second channel regions 8, and the overflow of charges that causes noise into the second channel regions from the overflow drain regions 14, can be prevented even in cases where the information charges are transferred to the second channel regions 8 beneath the transfer electrodes 10-1 in which protruding parts 18 are disposed.

At time t=t3, the potential applied to the transfer electrodes 10-3 rises from an L level to an H level. As a result, the information charges stored in the regions beneath the transfer electrodes 10-2 are stored in the regions beneath both the transfer electrodes 10-2 and the transfer electrodes 10-3 (state of potential distribution P4).

At time t=t4, the potential φ2 applied to the transfer electrodes 10-2 falls from an H level to an L level. As a result, the information charges stored in the regions of the transfer electrodes 10-2 are transferred to the regions of the transfer electrodes 10-3 (state of potential distribution P5).

At time t=t5, the potential φ1 applied to the transfer electrodes 10-1 rises from an L level to an H level. As a result, the information charges stored beneath the transfer electrodes 10-3 are stored beneath both the transfer electrodes 10-3 and the transfer electrodes 10-1 (state of potential distribution P6).

At time t=t6, φ3 falls from an H level to an L level, and the information charges stored beneath the first transfer electrodes 10-3 and 10-1 are transferred to the regions beneath the transfer electrodes 10-1 (state of potential distribution P7).

At time t=t7, φ2 rises from an L level to an H level, and the information charges stored in the regions beneath the first transfer electrodes 10-1 are stored beneath both the transfer electrodes 10-1 and the transfer electrodes 10-2 (state of potential distribution P8). As a result of the above operation, information charges are transferred from pixels where the information charges are accumulated to next pixels. The information charges are successively transferred by repeating the operation following the point where the OFD reaches the M level.

In the present embodiment, second channel regions 8 are not formed in the regions beneath the transfer electrodes 10-3, unlike the case of the transfer electrodes 10-1 and 10-2. As a result, a potential difference caused by the difference in the impurity concentration is generated between the regions beneath the transfer electrodes 10-3 and the regions beneath the transfer electrodes 10-1 and 10-2. This potential difference forms a barrier when the information charges are transferred, and there may be cases in which this leads to degradation in the transfer efficiency. Accordingly, it is desirable that voltage values that take the potential difference into account be applied to the respective transfer electrodes 10. For example, in a case where 2.9 V is applied as the H level of φ1 and φ2, it is desirable that 4.9 V be applied as the H level of φ3. Meanwhile, in a case where −5.8 V is applied as the L level of φ1 and φ2, it is desirable that −3.8 V be applied as the L level of φ3. Specifically, in regard to the potential level applied as φ3 during transfer driving, it is desirable to apply a specified voltage that is shifted further in the positive direction than the potential levels applied as φ1 and φ2 by a potential amount corresponding to the potential difference.

Furthermore, a method in which the information charges are transferred by applying three-phase transfer clocks, in which the phase of the variation between the H level and L level differs, to the three neighboring transfer electrodes 10-1 through 10-3, was indicated as the information charge transfer method. However, the driving of the CCD image sensor of the present invention is not limited to this; a method may be used in which the information charges are transferred by applying multi-phase transfer clocks with three or more phases.

The information charges that are transferred to the storage section 52 from the imaging section 50 are successively transferred to the horizontal transfer section 54 by the second transfer electrodes 10-4 through 10-6. The information charges that are transferred to the storage section 52 are basically transferred in the same manner as in the case of the imaging section 50. However, in the storage section 52, third channel regions 15 are disposed in the regions beneath all of the second transfer electrodes 10-4 through 10-6; accordingly, the transfer clocks φ4 through φ6 that are applied to the second transfer electrodes 10-4 through 10-6 can all be set at the same H level and the same L level.

### Embodiment 2

Next, a CCD solid-state image sensor constituting another embodiment of the present invention will be described.

FIG. 19 shows a schematic diagram of the area in the vicinity of the boundary between the imaging section 50 and storage section 52 in a CCD solid-state image sensor constituting Embodiment 2. FIG. 19 shows a plurality of first channel regions 4 which are disposed on the surface of the semiconductor substrate and which extend parallel to each other, second and third channel regions 8 and 15 which are disposed in the gaps between the first channel regions 4, separation regions 12 which electrically separate the channel regions of neighboring column (first through third channel regions 4, 8, and 15) from each other, overflow drain regions 14 that have protruding parts 18, first transfer electrodes 10-1 through 10-3, and second transfer electrodes 10-4 through 10-6.

The overflow drain regions 14 in the present embodiment are disposed in every other separation region 12. Furthermore, the overflow drain regions 14 extend along the center of each separation region 12, and unlike the overflow drain regions 14 in Embodiment 1, these overflow drain regions 14 have protruding parts 18 that extend toward both of the two neighboring second channel regions 8. As a result, during discharge driving, the information charges are discharged from the two neighboring second channel regions 8 into the overflow drain regions 14 disposed in the gaps between the two second channel regions 8. The protruding parts protrude toward both of the neighboring second channel regions, whereby the information charges can be discharged into the drain regions from the second channel regions with good efficiency during discharge driving. Furthermore, the drain regions are disposed in every other separation region, whereby the overflow of the information charges into the separation regions in which no drain regions are disposed can be reliably prevented.

Furthermore, in the second embodiment as well, the protruding parts 18 may be disposed in the regions beneath the first transfer electrodes 10-2.

Furthermore, the third channel regions 15 formed in the storage section 52 have a narrower width than the second channel regions 8 formed in the imaging section 50. As a result, a sufficient distance can be ensured between the overflow drain regions 14 and third channel regions 15, and the overflow of the information charges transferred to the storage section 52 into the overflow drain regions 14 can be prevented.

Furthermore, the discharge, accumulation, and transfer driving of the charge in the present embodiment can be performed in the same manner as in Embodiment 1.

### Embodiment 3

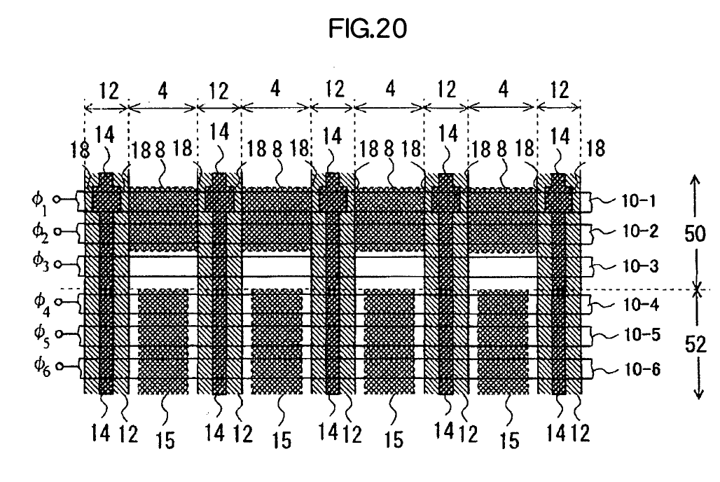

FIG. 20 shows a schematic diagram of the area in the vicinity of the boundary between the imaging section 50 and storage section 52 in a CCD solid-state image sensor constituting a third embodiment. In FIG. 20, as in FIG. 19, first channel regions 4, second channel regions 8, third channel regions 15, separation regions 12, overflow drain regions 14 that have protruding parts 18, first transfer electrodes 10-1 through 10-3, and second transfer electrodes 10-4 through 10-6 are shown.

The overflow drain regions 14 in the present embodiment are disposed in all of the separation regions 12; these overflow drain regions 14 extend along the center of each separation region 12, and the respective overflow drain regions 14 have protruding parts 18 that protrude toward both of the neighboring second channel regions 8. In the discharge driving of the present embodiment, the information charges stored in the second channel regions 8 are discharged into the two neighboring overflow drain regions 14 via the protruding parts 18.

Furthermore, in the present embodiment as well, it is desirable that the second channel regions 8 be formed without any substantial gaps being left between these regions and the separation regions 12, and that the width of the third channel regions 15 in the storage section 52 be smaller than the width of the second channel regions 8 in the imaging section 50. Furthermore, the protruding parts 18 may also be disposed in the regions beneath the first transfer electrodes 10-2.

Furthermore, the discharge, accumulation, and transfer driving of the charge in the present embodiment can be performed in the same manner as in the first embodiment.

In the solid-state image sensor of the present invention, as a result of the overflow drain regions having protruding parts that protrude toward the second channel regions, the following merit is obtained: namely, there is no overflow of the charges into the second channel regions from the overflow drain regions during transfer driving, and the superimposition of noise on the information charges can be prevented.

What is claimed is:

1. A solid-state image sensor comprising a plurality of first channel regions of a second conduction type which are disposed parallel to each other on a principal surface of a semiconductor substrate of a first conduction type, overflow drain regions of the second conduction type which are disposed between neighboring first channel regions, a plurality of separation regions of the first conduction type which are disposed between the first channel regions and the overflow drain regions, and a plurality of first transfer electrodes which are formed over the plurality of first channel regions and which are disposed parallel to each other in a direction perpendicular to the plurality of first channel regions, the solid-state image sensor further comprising:
second channel regions of the second conduction type which are disposed on the principal surface of the semiconductor substrate in positions corresponding to the regions where the first channel regions and specified first transfer electrodes intersect, and which have a higher concentration than the first channel regions; and
the overflow drain regions adjacent to the second channel regions having protruding parts that protrude toward the second channel regions.

2. The solid-state image sensor of claim 1, wherein
the second channel regions are disposed in positions corresponding to the regions where the first channel regions and at least two neighboring first transfer electrodes intersect, and
the protruding parts protrude toward one of the neighboring second channel regions, and the number of first transfer electrodes disposed over the protruding parts is smaller than the number of first transfer electrodes disposed over second channel regions.

3. The solid-state image sensor of claim 1, wherein
the second channel regions are disposed in positions corresponding to the regions where the first channel regions and at least two neighboring first transfer electrodes intersect, and
the protruding parts protrude toward both of the neighboring second channel regions, and the number of first transfer electrodes disposed over the protruding parts is smaller than the number of first transfer electrodes disposed over the second channel regions.

4. The solid-state image sensor of claim 1, wherein
the overflow drain regions are formed on every other separation region,
the second channel regions are disposed in positions corresponding to the regions where the first channel regions and at least two neighboring first transfer electrodes intersect, and
the protruding parts protrude toward both of the neighboring second channel regions, and the number of first transfer electrodes disposed over the protruding parts is smaller than the number of first transfer electrodes disposed over the second channel regions.

5. The solid-state image sensor of claim 2, wherein the first channel region is present between the second channel region and the separation region.
